(19) United States
(12) Patent Application Publication
(10) Pub. No.: US 2006/0110917 A1
(43) Pub. Date: May 25, 2006

(54) Method of metallization in the fabrication of integrated circuit devices

(76) Inventors: Shu-Jen Chen, Hsin-Chu City (TW); Chia-Lin Hsu, Tai-Nan City (TW); Kun-Hsien Lin, Tainan County (TW)

Correspondence Address: NORTH AMERICA INTELLECTUAL PROPERTY CORPORATION, P.O. BOX 506, MERRIFIELD, VA, 22116, US

(21) Appl. No.: 11/163,055

(22) Filed: Oct. 3, 2005

Related U.S. Application Data
(60) Provisional application No. 60/522,906, filed on Nov. 19, 2004.

(51) Int. Cl. H01L 21/44

(52) U.S. Cl. 438/653; 438/687; 438/675; 438/660

(57) ABSTRACT

The method of metallization in the fabrication of an integrated circuit device comprises the steps as follows. First, a dielectric layer overlying a semiconductor substrate is provided. The dielectric layer has a top surface and a plurality of openings. Next, a metal layer is formed on the dielectric layer and filling the openings. Subsequently, a first removing process is performed to partially removing the metal layer. A first annealing process is performed on the metal layer. Finally, a second removing process is performed to remove the metal layer completely to leave the metal layer only within the openings.

### CROSS REFERENCE TO RELATED APPLICATIONS

This application claims priority from U.S. provisional application No. 60/522,906 by Chen et al., filed Nov. 19, 2004, entitled “A method of Cu film stress management for Cu damascene process”.

### BACKGROUND OF THE INVENTION

1. Field of the Invention

The present invention relates to a method of metallization in the fabrication of integrated circuits, and more particularly, to a method of reducing the formation of hillocks in metallization in the manufacture of integrated circuits.

2. Description of the Prior Art

In the manufacture of integrated circuits, after individual devices such as transistors have been fabricated in and on the semiconductor substrate, they must be connected together to perform the desired circuit functions. This interconnection process is generally called “metallization” and is performed using a number of different photolithographic, deposition, and removal techniques.

A number of interconnection processes are developed. Individual and multiple levels of single and dual damascene structures can be formed for single and multiple levels of channels and vias, which are collectively referred to as “interconnects”. For these interconnections, metals such as aluminum, aluminum alloys, or copper are the preferred materials. In a common application for integrated circuit fabrication, a contact/via opening is etched through a dielectric layer to an underlying conductive area to which electrical contact is to be made. A conducting layer material is deposited within the contact/via opening. Because of its lower bulk resistivity, copper (Cu) metallization is the future technology for feature sizes of 0.18 microns and below. Often, a damascene or dual damascene process is used to provide Cu metallization. The copper is deposited within the damascene opening and polished back. Then, a capping layer, such as silicon nitride or silicon carbide, is deposited over the copper plugs and wires to prevent copper from diffusing into overlying layers.

The deposition and processing of a layer of semiconductor material typically creates a thin film of material in which molecular stress is introduced due to the thermal processing of the deposited layer. This thermal stress results in the accumulation of sub-layers of the material, which show themselves as hillocks over the surface of the created thin film. This occurrence of surface hillocks is particularly troublesome where multiple overlying layers of copper are used as part of the structure since lower layer hillocks will have a magnifying effect on overlying layers of copper.

For improving the Copper film CMP removal rate stability and interconnection line reliability, current Cu damascene processes usually put an annealing step after ECP (electro chemical plating) and CMP (chemical mechanical polishing). FIGS. 1-3 schematically illustrate in cross-sectional representation a conventional method. Referring to FIG. 1, there is illustrated a portion of a partially completed integrated circuit device. There is shown a semiconductor substrate 10, preferably composed of single crystalline silicon. Semiconductor device structures may be formed in and on the semiconductor substrate. For example, gate electrodes and source/drain regions as well as lower levels of metallization may be formed. The semiconductor device structures, not shown, are contained in layer 14.

A dielectric layer 20, composed of silicon dioxide, borophosphosilicate glass (BPSG), borosilicate glass (BSG), phosphosilicate glass (PSG), or the like, is deposited over the semiconductor structures to a thickness of between about 100 and 10,000 Angstroms and preferably planarized. A contact/via opening 22 is etched through the dielectric layer 20 to one of the semiconductor device/interconnect structures within the layer 14, not shown. The opening 22 may be another one such as a single or dual damascene opening.

A barrier layer may be deposited, not shown. A copper layer 30 is deposited to fill the opening 22, as shown in FIG. 2. The copper layer may be deposited by physical or chemical vapor deposition, electroplating, or electroless plating, for example. After the formation of the copper layer, the copper layer is usually annealed. Due to the large thickness of such formed copper layer, the temperature for annealing is relatively low for scrupling the void and hillock generation. Referring now to FIG. 3, the copper layer is polished such as by CMP to leave the copper layer only within the opening. After the CMP process, the resulting copper layer is annealed.

Thin layers of conducting, semiconducting, and dielectric materials may be deposited by a number of deposition techniques. Common deposition techniques in modern processing include physical vapor deposition (PVD), also known as sputtering, chemical vapor deposition (CVD), plasma-enhanced chemical vapor deposition (PECVD), and electrochemical plating (ECP).

Chemical mechanical planarization, or chemical mechanical polishing (CMP), is a common technique used to planarize/polish substrates. CMP utilizes a chemical composition, typically a slurry or other fluid medium, for selective removal of materials from substrates. In conventional CMP techniques, a substrate carrier or polishing head is mounted on a carrier assembly and positioned in contact with a polishing pad in a CMP apparatus. The carrier assembly provides a controllable pressure to the substrate, thereby pressing the substrate against the polishing pad. The pad is moved relative to the substrate by an external driving force. The CMP apparatus affects polishing or rubbing movements between the surface of the substrate and the polishing pad while dispersing a polishing composition to affect chemical activitities and/or mechanical activities and consequential removal of materials from the surface of the substrate.

Another planarization/polishing technique is electro chemical mechanical polishing (ECMP). ECMP techniques remove conductive materials from a substrate surface by electrochemical dissolution while concurrently polishing the substrate with reduced mechanical abrasion compared to conventional CMP processes. The electrochemical dissolution is performed by applying a bias between a cathode and a substrate surface to remove conductive materials from the substrate surface into a surrounding electrolyte. Typically, the bias is applied by a ring of conductive contacts to the substrate surface in a substrate support device, such as a substrate carrier head. Mechanical abrasion is performed by positioning the substrate in contact with conventional polishing pads and providing relative motion there between.

In the conventional metallization process, one major problem relates to the formation of hillocks in the copper surface, which are due to grain growth causing stress at elevated temperatures. A hillock is a protrusion of copper from the copper surface. Hillocks tend to form most readily at free surfaces where there are no constraining films, but they can also protrude through thin films if the stresses are high enough. The hillocks can extend into both the capping layer and the dielectric layer. If the hillocks are large enough, they can result in causing short circuit types of defects either immediately or over time, which irrevocably damage the integrated circuit.

For getting better Rs and hillock defect data, the annealing temperature after copper plating might be higher and higher and such high temperature will likely lead to void generation and cause low product yield. Furthermore, the annealing after Cu CMP will induce hillock defects dramatically when the stresses are not fully released during the annealing after the copper plating.

Copper hillocks reduce copper reliability and confuse defect inspection tools. Reduction of copper hillocks in the copper metallization process becomes more and more important for yield and reliability improvement. It is desired to reduce copper hillock generation in the copper metallization process.

### SUMMARY OF THE INVENTION

A main objective of the present invention is to manufacture metal interconnects or via/contacts that have reduced stress therein and are free of hillocks, such that the resulting semiconductor devices may have increased reliability.

In accordance with one embodiment of the objective of the present invention, the method of metallization in the fabrication of an integrated circuit device comprises the steps as follows. First, a dielectric layer overlying a semiconductor substrate is provided. The dielectric layer has a top surface and a plurality of openings. Next, a metal layer is formed on the dielectric layer and filling the openings. Subsequently, a first removing process is performed to partially removing the metal layer. A first annealing process is performed on the metal layer. Finally, a second removing process is performed to remove the metal layer completely to leave the metal layer only within the openings.

In accordance with another embodiment of the objective of the present invention, the method of metallization in the fabrication of an integrated circuit device comprises the steps as follows. A dielectric layer overlying a semiconductor substrate is provided. The dielectric layer has a top surface and a plurality of openings. A barrier layer is formed on the dielectric layer and the sidewall and bottom of the openings. A seed layer is formed over the barrier layer. An electroplating process is performed to form a copper layer over the seed layer. Next, the copper layer is partially removed back. Then, a first annealing process is performed on the copper layer. The electroplating process is continued. Finally, the copper layer is removed back completely to leave the copper layer only within the openings.

In the method of metallization in the fabrication of integrated circuits according to the present invention, a conventional CMP process is divided into two stages with an annealing process therebetween. After the first stage of the CMP process, the remaining metal layer is controlled to be thin but continuous. The atoms of the metal layer rearrange to reduce the stress occurring from deposition during the annealing at a relatively high temperature, which results in a reduced number of hillocks in the resulting metal layer, especially for a copper layer. Therefore, the copper film stress can be controlled by controlling the thickness of copper film during annealing or by adding an annealing step after copper film partial removal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 schematically illustrate in cross-sectional representation a conventional method;

FIGS. 4-8 illustrate one embodiment of the method of metallization in the fabrication of an integrated circuit device according to the present invention; and

FIG. 9 shows a process flow chart for another embodiment of the method of metallization in the fabrication of an integrated circuit device according to the present invention.

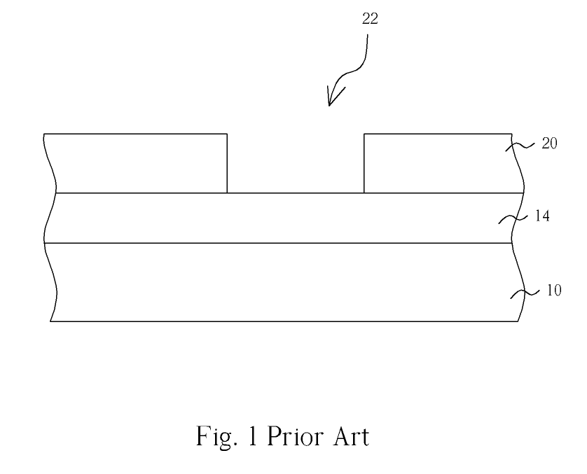

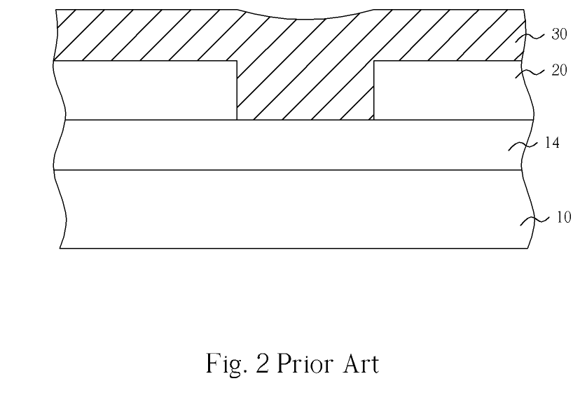

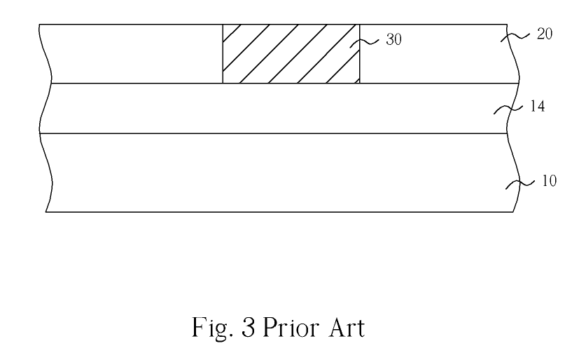

### DETAILED DESCRIPTION

From the observation of the inventors to a copper film stress hystersis, it is summarized that the stress release is irreversible and leads to higher tensile stress after annealing, and stress relaxation starts at a temperature higher than about 170° C. for the first time of annealing. Thus, it can be rationally presumed that the grains start reconstruction/rearrangement when the temperature is higher than 170° C.

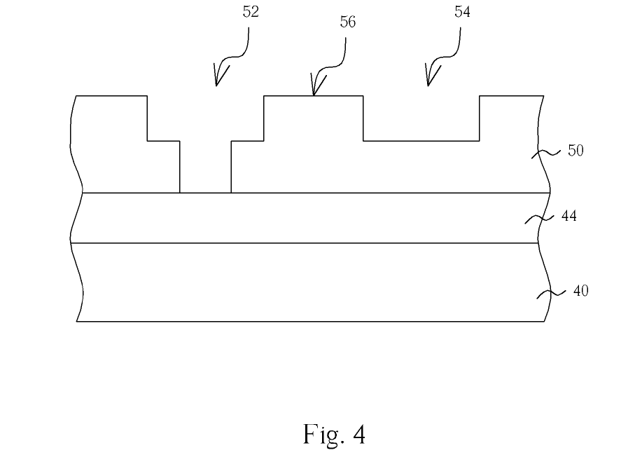

FIGS. 4-8 illustrate one embodiment of the method of metallization in the fabrication of an integrated circuit device according to the present invention. Refer to FIG. 4 showing a schematic cross section of a portion of a partially completed integrated circuit device. There is shown a semiconductor substrate 40, preferably composed of single crystalline silicon. Semiconductor devices structures may be formed in and on the semiconductor substrate. For example, gate electrodes and source/drain regions as well as lower levels of metallization may be formed. The semiconductor device structures, not shown, are contained in layer 44.

A dielectric layer 50, composed of silicon dioxide, borophosphosilicate glass (BPSG), borosilicate glass (BSG), phosphosilicate glass (PSG), or the like, is deposited over the semiconductor structures to a thickness of between about 100 and 10,000 Angstroms and preferably planarized. The dielectric layer 50 has a top surface 56.

A space or an opening for a dual damascene structure 52 and a trench or an opening 54 for an interconnect are etched through and in the dielectric layer 50, respectively. The openings 52 and 54 may be openings for a single damascene or a contact/via.

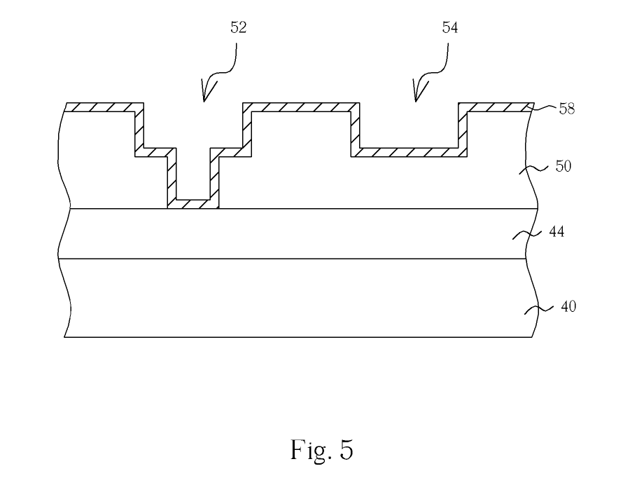

Referring to FIG. 5, a barrier layer 58 may be deposited on the dielectric layer 50, and the walls and bottoms of the openings 52 and 54. The barrier layer may comprise a silicon nitride layer, a titanium (Ti) layer, a tantalum (Ta) layer, a titanium nitride layer (TiN layer), a tantalum nitride layer (TaN layer), a tantalum nitride layer/tantalum composite layer, a Ti/TiN/Ti layer, or a Ta/TaN/Ta layer.

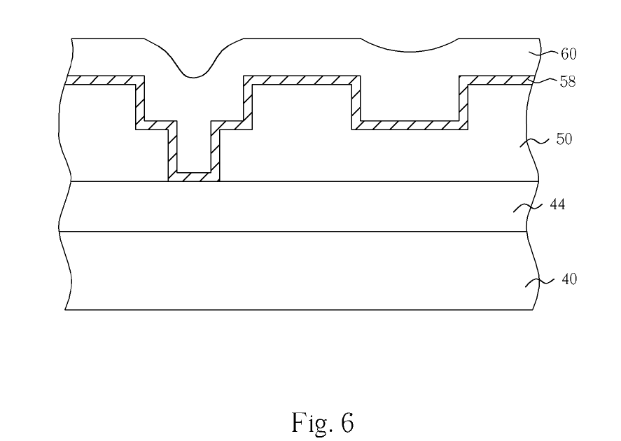

Referring to FIG. 6, a metal layer 60 is deposited to fill the openings 52 and 54, as shown in FIG. 5. The metal layer may be deposited by a physical vapor deposition (PVD) process, a chemical vapor deposition (CVD) process, a plasma-enhanced chemical vapor deposition (PECVD) process, an electroplating process such as electrochemical plating (ECP) process, or electroless plating, for example. The metal layer may comprise copper. After the deposition of the metal layer, the metal layer may be annealed at a temperature in the range of about 100 to 250° C. Because the metal layer now is thick, the temperature is preferably low, thereby the metal layer won't suffer a lot of voids and hillocks.

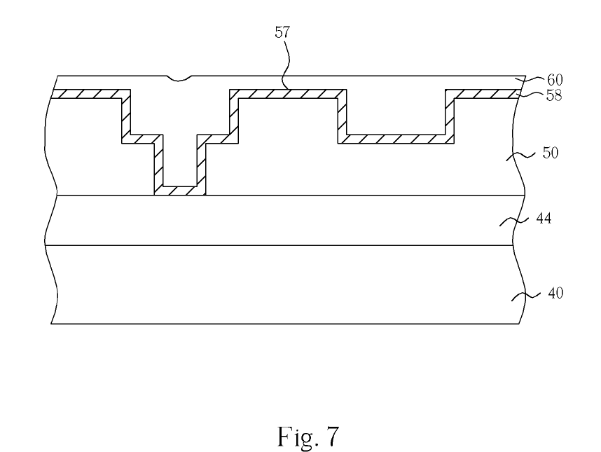

Referring now to FIG. 7, the metal layer 60 is partially removed to leave the metal layer within the openings and continuously on the surface 57 over the dielectric layer 50. The removal of the metal layer may be accomplished by a chemical mechanical polishing (CMP) process, an electro chemical mechanical polishing (eCMP) process, an electro chemical polishing process, or an electro polishing process. The remaining metal layer on the surface 57 may preferably have a thickness of 500 to 3500 angstroms.

After the partial removal of the metal layer 60, an annealing process is performed on the remaining metal layer 60. It is noted that as the reaming metal layer 60 is relatively thin, the annealing temperature may be relatively high, such as between 150 and 450° C. The high temperature allows atoms of the metal layer to rearrange such that the metal layer is not stressed. Thus, hillocks of the metal layer do not occur.

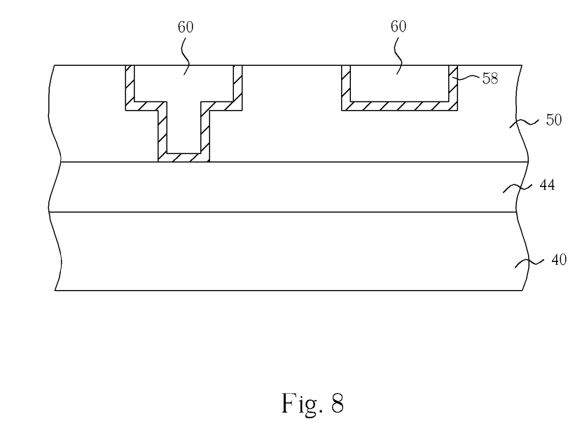

Referring to FIG. 8, a CMP process is performed to remove the metal layer 60 and the barrier layer 58 completely to leave the metal layer and the barrier layer only within the openings. The metallization in the fabrication of an integrated circuit device may be accomplished after the complete removal, as the metal layer has been annealed at a relatively high temperature in the previous step. The resulting metal layer for the integrated circuit device may have already met the required electric properties, such that a post-CMP annealing may be performed or may be skipped. If it is performed, the annealing temperature may be from 150 to 450° C., for example.

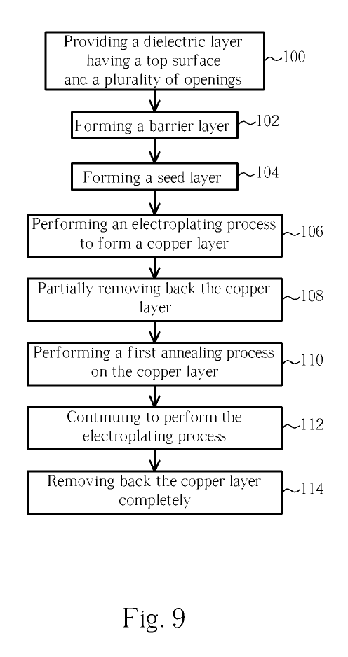

FIG. 9 shows a process flow chart for another embodiment of the method of metallization in the fabrication of an integrated circuit device according to the present invention. First, in step 100, a dielectric layer is provided overlying a semiconductor substrate. The dielectric layer has a top surface and a plurality of openings. Next, in step 102, a barrier layer is formed on the dielectric layer and the sidewall and bottom of the openings. In step 104, a seed layer is formed over the barrier layer. For conductive materials such as copper, which are deposited by electroplating, a seed layer is usually deposited on the barrier layer and lines the barrier layer in the opening. The seed layer, generally formed of copper, is deposited to act as an electrode and a nuclei layer for the electroplating process. The seed layer may be formed by a physical vapor deposition to have a thickness between 5 and 2000 angstroms. In step 106, an electroplating process is performed to form a copper layer over the seed layer. The electroplating process may be an electrochemical plating (ECP) process, for example.

Subsequently, in step 108, the copper layer is partially removed back. Similar to the embodiment according to the present invention mentioned in the above description, partially removing back the copper layer involves removing part of the copper layer to leave the copper layer continuously on the seed layer. The remaining copper layer is not discrete in parts. The removal may be accomplished by a chemical-mechanical polishing (CMP) process, an electro chemical mechanical polishing (eCMP) process, an electro chemical polishing process, or an electro polishing process.

Subsequently, in step 110, an annealing process is performed on the remaining copper layer. The annealing temperature is preferably in a range of 150 to 450° C. In step 112, the electroplating process is continued to deposit copper. It is noted that the step of performing an electroplating process, the step of removing back the copper layer, and the annealing process may be performed in a single chamber, because both electroplating process and removing back the copper layer by eCMP or electro chemical polishing need an electrochemical process.

Finally, in step 114, the copper layer, the seed layer, and the barrier layer are removed back completely to leave the copper layer, the seed layer, and the barrier layer only within the openings. The metallization in the fabrication of an integrated circuit device according to the present invention may be complete at this point or may further comprise a step of performing a post-CMP annealing process on the copper layer. The annealing temperature is preferably in a range of 150 to 450° C.

Experiment

A lot of wafers were divided into five groups for the experiment.

For Comparison Group 1: The wafers were subjected to a copper deposition by ECP, and then, to a normal copper CMP to completely remove excess copper.

For Base Line Group 2: The wafers were subjected to a copper deposition by ECP, then, a normal copper CMP to completely remove excess copper, and finally a post-CMP annealing at 200° C. for 30 minutes.

For Exemplary group 3: The wafers were subjected to a series of treatments as follows: a copper deposition by ECP, a partial copper CMP, an annealing at 350° C. for 3 minutes, then, a normal copper CMP to completely remove excess copper and barrier, and finally a post-CMP annealing at 350° C. for 3 minutes.

For Exemplary group 4: The wafers were subjected to a series of treatments as follows: a copper deposition by ECP, a partial copper CMP, an annealing at 350° C. for 3 minutes, and, then, a normal copper CMP to completely remove excess copper and barrier. No post-CMP annealing is performed.

For Exemplary group 5: The wafers were subjected to a series of treatments as follows: a copper deposition by ECP, a partial copper CMP, an annealing at 350° C. for 6 minutes, and, then, a normal copper CMP to completely remove excess copper and barrier. No post-CMP annealing is performed.

All of the wafers of Groups 1-5 were subjected to a qualified wafer acceptable test. In the result, for the defect inspection, Group 2 as a base line had a great number (such as 2303) of defects, Group 1 as a comparison example had a mediocre number (such as 118) of defects, and Groups 3, 4, and 5 as examples according to the present invention has few defects (such as 9, 15, and 12, respectively).

In the present application, two stages of CMP processes are performed. After the first CMP process such as by Cu CMP, e-CMP, or electropolish related techniques, the copper layer is partially removed and the resulting copper layer is relatively thin; therefore, the annealing temperature can be made higher without scruples of the void and hillock generation. Accordingly, the stress value can be managed by controlling the thickness and annealing temperature of the copper layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of metallization in the fabrication of an integrated circuit device comprising:
providing a dielectric layer overlying a semiconductor substrate, wherein the dielectric layer has a top surface and a plurality of openings;
forming a metal layer overlying the dielectric layer and filling the openings;
performing a first removing process to partially removing the metal layer;
performing a first annealing process on the metal layer; and
performing a second removing process to remove the metal layer completely to leave the metal layer only within the openings.

2. The method of claim 1, wherein the step of performing a first removing process to partially removing the metal layer is to remove part of the metal layer to leave the metal layer within the openings and continuously on the top surface of the dielectric layer.

3. The method of claim 1, wherein the metal layer comprises copper.

4. The method of claim 3, wherein the first annealing process is performed at a temperature in a range of 150° C. to 450° C.

5. The method of claim 1, after performing a second removing process to remove the metal layer completely to leave the metal layer only within the openings, further comprising a step of performing a second annealing process on the metal layer.

6. The method of claim 5, wherein the metal layer comprises copper and the second annealing process is performed at a temperature in a range of 150° C. to 450° C.

7. The method of claim 1, wherein a barrier layer is formed on the dielectric layer and the sidewall and bottom of the openings.

8. The method of claim 1, wherein the openings are ones selected from the group consisting of a trench, a via hole, a contact hole, a space for a single damascene structure, and a space for a double damascene structure.

9. The method of claim 1, wherein forming a metal layer overlying the dielectric layer and filling the openings is performed by a physical vapor deposition (PVD) process, a chemical vapor deposition (CVD) process, a plasma-enhanced chemical vapor deposition (PECVD) process, or an electrochemical plating (ECP) process.

10. The method of claim 1, wherein polishing the metal layer is performed by a chemical mechanical polishing (CMP), an electro chemical mechanical polishing (eCMP) process, an electro chemical polishing process, or an electro polishing process.

11. The method of claim 1, before performing a first removing process to partially removing the metal layer, further comprising a step of performing a third annealing on the metal layer.

12. The method of claim 11, wherein the metal layer comprises copper and the third annealing process is performed at a temperature in a range of 100° C. to 250° C.

13. A method of copper metallization in the fabrication of an integrated circuit device comprising:
providing a dielectric layer overlying a semiconductor substrate, wherein the dielectric layer has a top surface and a plurality of openings;
forming a barrier layer on the dielectric layer and the sidewall and bottom of the openings;
forming a seed layer over the barrier layer;
performing an electroplating process to form a copper layer over the seed layer;
partially removing back the copper layer;
performing a first annealing process on the copper layer;
continuing to perform the electroplating process; and
removing back the copper layer completely to leave the copper layer only within the openings.

14. The method of claim 13, wherein partially removing back the copper layer is to remove part of the metal layer to leave the metal layer continuously on the seed layer.

15. The method of claim 13, wherein the electroplating process is an electrochemical plating (ECP) process.

16. The method of claim 13, wherein removing back the copper layer completely to leave the copper layer only within the openings is accomplished by a chemical-mechanical polishing (CMP) process, an electro chemical mechanical polishing (eCMP ) process, an electro chemical polishing process, or an electro polishing process.

17. The method of claim 16, wherein the step of performing an electroplating process, the step of removing back the copper layer, and the annealing process are performed in a single chamber.

18. The method of claim 13, wherein the first annealing process is accomplished at a first temperature in a range of 150 to 450° C.

19. The method of claim 13, after removing back the copper layer completely to leave the copper layer only within the openings, further comprising a step of performing a second annealing process on the copper layer at a second temperature in a range of 150 to 450° C.
